(19) United States
(12) Patent Application Publication
(10) Pub. No.: US 2010/0252306 A1
(43) Pub. Date: Oct. 7, 2010

(54) INTERCONNECT SUBSTRATES, METHODS AND SYSTEMS THEREOF

(75) Inventors: Uri Mirsky, Nofit (IL); Shimon Neftin, Kiryat Shmonah (IL); Lev Furer, Haifa (IL)

Correspondence Address: BROWDY AND NEIMARK, P.L.L.C.;624 NINTH STREET, NW, SUITE 300, WASHINGTON, DC, 20001-5303, US

(73) Assignee: Micro Components Ltd., Migdal IIa'emek (IL)

(21) Appl. No.: 12/601,632

(22) PCT Filed: May 25, 2008
(86) PCT No.: PCT/IL08/00706

§ 371 Date: May 24, 2010

Related U.S. Application Data
(60) Provisional application No. 60/924,653, filed on May 24, 2007.

(51) Int. Cl. H05K 1/00; H05K 3/00; C25D 11/02; C25D 5/00; C25D 11/04

(52) U.S. Cl. 174/252; 29/846; 205/333; 205/171; 205/324

(57) ABSTRACT

A method of enhancing thermal management of an electronic device comprising the steps of; forming an ALOX™ interconnect substrate; taking an electronic device; and interconnecting the electronic device to the interconnect substrate to yield a substantial split of thermal and electrical paths in the interconnect substrate.

### FIELD

The present invention relates to the field of electronics, in particular to interconnect substrates, methods and systems thereof. Specifically it concerns methods and systems of effectively removing heat from high power ALOX™ packages.

### BACKGROUND

Microelectronics packaging and interconnection technologies have evolved to serve the trend to miniaturizing in microelectronic devices and overall electronics equipment in military, telecommunications, illumination, industrial and consumer applications. The trend has been driven by various forces including specialized requirements, such as, but not limited to: size; weight; performance; and cost, which have led to innovations of integrated circuit packaging and development in connectivity on electronics substrates and circuit boards.

Examples of microelectronic device packaging range from a simple light emitting diode (LED) die, which is basically a simple diode junction with two terminals, to complex microprocessors' integrated circuit chips (ICC, or IC) having multiple input and output terminals, which are interfaced with other components and devices. An IC is also referred to as an “electronic device” or a “microelectronic device” in the specification and claims which follow.

In a broad sense, “microelectronic packaging” can simply be viewed as a way to interface an IC (or a “die”, the plural of which is “dice”) with peripherals such as a power source (for example, power supply, battery, and the like), an input device (for example, keyboard, mouse, and the like), and an output device (for example, monitor, modem, antenna, and the like). Interfacing the IC with peripherals, meaning transferring signals in and out of the IC as well as providing operating power to the IC, is typically done with wires and/or conductive traces on a printed wiring board (PWB), also referred to as a printed circuit board (PCB). Such interfacing is commonly referred to as “interconnection”.

Thermal management of microelectronic devices deals with maintaining desirable operating temperatures of the devices by removing heat generated by the microelectronic devices. Typically, thermal management efforts are integral to the design and fabrication of the device itself. In some simple semiconductor dice, as well as in most complex ICs, a major challenge in thermal management is to reduce thermal resistance of thermal paths from the heat source (namely, the die or IC) to the outside world from where the heat can be removed by: convection (such as by air, coolant or other); conduction; and/or by radiation. The term “thermal path”, as used hereinbelow in the specification and in the claims, is intended to mean the combination and/or juxtaposition of structures and material layers that allow a substantial portion of heat to flow from a microelectronic device to the outside world—usually by thermal conduction along the thermal path. The term “electrical path”, as used hereinbelow in the specification and in the claims which follow, is intended to mean the combination and/or juxtaposition of structures, material layers, and wires that allow the electrical transfer of signals and/or power to and from the microelectronic device to, inter alia, a PCB, other devices, and other addresses. The terms “electronic package” and/or “microelectronic package” as used hereinbelow in the specification and the claims which follow mean the overall structure and/or package formed by providing electrical and thermal paths for a microelectronic device.

One major part of a thermal path is the substrate (the “board”, “chip carrier” or multi-layer (or multilayer) interconnect board carrier, substrate, or interposer) on which a die to be cooled is mounted. Examples of such substrates are: PWB; PCB; and a Ball Grid Array (BGA) of various types. As noted hereinabove, the die is interconnected with the substrate, and the substrate may thus be referred to as an “interconnect substrate”. As used herein and in the claims which follow, an “interconnect substrate” is typically a flat substrate used to connect electronic components with one another and having patterns of conductive traces in at least one layer for effecting routing of signals and power from one electronic component to another, or to the outside world. Typically, an interconnect substrate has many metallization layers with the conductive traces, and vias (the definition hereinbelow, on page 5) connect selected traces from one layer to selected traces of another layer.

One function of an interconnect substrate is to “spread pitch”, that is, to take interconnections which are spaced relatively very close together (such as, but not limited to bond pads on an IC) and to space them further apart to allow interconnection to another device (such as a PWB or a BGA substrate). Another function of the interconnect substrate is to enable one type of connection to another, such as, but not limited to: from a wire bond from an IC to a solder bump for a surface mounting a device.

One example of an interconnect substrate is an “interposer”. The term “interposer” is used in the specification and the in the claims which follow to mean an intermediate layer or structure that provides an electrical connection between the die and the package. Generally, the interposer may perform a pitch-spreading function, but the interposer typically does not “translate” connection types (meaning typically having a connection type common to both the “entering” side and the “exiting” side), and it often provides a thermal management function.

One objective of an interconnect substrate is to electrically connect two electronic components with one another. One example of a simplified connection is a simple two terminal device (such as a simple resistor having two leads). In this case, the leads may pass through two holes in a PWB to conductors on the underside of the PWB. A conductive trace may be employed on the PWB, the trace passing under a body portion of the two-terminal device (without connecting to it). This example is a relatively straightforward interconnect substrate example. However, with more complex electronic devices having many terminals, such as multiple input/output (I/O) connections, multiple “crossovers” as known in the art, are employed to effect complex routing of signals (to a lesser extent, power). A solution to this topological/routing problem is found in multilayer interconnect technology.

A key element in multilayer interconnect technology is a “via”, as known in the art: an electrical connection between two or more conductive layers. For example, a via may include an electrical connection between adjacent metal layers separated by a dielectric material. In another example, in ALOX technology, a via may include an electrical connection between a top and a bottom conductive layer. Between these layers an inner aluminum layer, not connected by this via, and two dielectric layers, may be present. In conventional substrate technologies, a dielectric sheet is used as a base material, in which the via is formed using drilling (and/or etching and/or punching) and via hole plating processes.

One via type is a “blind” via, which extends through one or more dielectric layers to a conductive trace on an inner metal layer, as opposed to a via passing completely through the entire substrate thickness. Another blind via (or vias) may extend through the remaining dielectric layers at other positions on the conductive trace. Such vias could be useful for pitch spreading and/or for effecting complex interconnections.

In addition to the function of providing electrical connectivity between conductive traces on two different (typically adjacent) metal layers, vias frequently also serve an important role in conducting heat away from an operating electronic device mounted on the substrate. Typically, with a dielectric-based substrate (such as a ceramic substrate), the bulk of the substrate material is a poorer thermally-conductive ceramic material, in which case a plurality of vias may be formed and filled with thermally conductive material to improve thermal conduction of heat from the device through the substrate.

ALOX™ substrate technology and its applications are described in the following patents and publications: U.S. Pat. No. 5,661,341; U.S. Pat. No. 6,448,510; U.S. Pat. No. 6,670,704; International Patent Publication No. WO 00/31797; International Patent Publication No. WO 04/049424; and U.S. Patent Application Publication No. 2007/0080360, all by one or more inventors of the current invention, whose disclosures are incorporated herein by reference.

ALOX™ substrate technology is a unique multilayer substrate technology developed for microelectronics packaging applications. ALOX™ substrate technology does not require drilling and hole plating, meaning the via is formed of solid aluminum, and the dielectric is of a high quality ceramic nature. The ALOX™ process is simple and low cost, and contains a low number of process steps. The technology serves as a wide technology platform, and can be implemented in various electronics packaging applications such as, but not limited to: RF; SiP; 3-D memory stacks; MEMS; and high power modules and components.

The starting material in the ALOX™ process is a conductive aluminum sheet. A first step in the process is selectively masking the top and bottom of the sheet using conventional masking techniques (for example, photoresist, also referred to herein as “resist”). Via structures are formed by selective anodization of the sheet through the entire thickness of the sheet. In the process of selective anodization, the exposed areas of the aluminum sheet are converted into aluminum oxide, which is ceramic in nature and a relatively highly insulating dielectric material. The protected, unexposed areas of the aluminum sheet retain their aluminum nature and serve as connecting vias.

In its simplest form, an ALOX™ interconnect substrate is formed by electrochemical anodic oxidation of selected portions of an initially conductive valve metal (for example, aluminum) substrate resulting in regions of conductive material (belonging to the initial aluminum sheet) which are geometrically defined and isolated from one another by regions of anodized (typically non-conductive, such as aluminum oxide, or alumina) “isolation structures”, the term used hereinbelow in the specification and in the claims for this purpose. A “valve metal” is meant to mean herein and in the claims which follow: a metal, such as aluminum, which is normally electrically conductive, but which can be modified, such as by oxidation to be both an electrical non-conductor (insulator) and a chemically resistant material. Valve metals include, but are not limited to: aluminum (Al, including Al 5052, Al 5083, Al 5086, Al 1100, Al 1145, and the like), titanium, tantalum, niobium, europium, and beryllium.

Isolation structures can extend into the substrate (in what is referred to as a “vertical” direction), including completely through the substrate. Isolation structures can also extend laterally (in what is called a “horizontal” direction) across the substrate, generally vertically just within a surface thereof. Anodizing from one or both sides of the substrate can be performed to yield complex interconnect structures.

In a more complex form (such as disclosed in U.S. Pat. No. 6,670,704) a multilayer, low cost ceramic board is formed. A complete “three metal layer” core contains an internal aluminum layer, top and bottom patterned copper layers with through vias and blind vias incorporated in the structure. ALOX™ technology offers a very simple and low cost production process; an excellent thermal performance product; and superior mechanical and electrical properties. The technology is further and more specifically illustrated in FIGS. 1A and 1B in U.S. Patent Application Publication No. US 2007/0080360, incorporated herein by reference.

Reference is presently made to FIG. 1, which is a schematic cross sectional view of a prior art typical high power chip package 10 mounted on a substrate 12. Typically, chip package 10 is mounted onto substrate 12 to allow desired electrical and thermal connections from the chip package to substrate 12 and to allow electrical connections to and from the substrate, as known in the art. In the exemplary schematic configuration shown, electrical connections 20 serve to connect the chip package through the substrate to balls 22.

Balls 22 are connected electrically to other components such as, but not limited to: power sources, other electronic components, and loads (all not shown in the current figure). Typically, thermal paths 25 serve to remove heat from chip package 10. Thermal paths 25 may coincide with electrical connections 20, in the form of vias, as described hereinabove. Generally, it can be seen in the exemplary schematic configuration that thermal paths 25 take advantage of the substrate and the electrical connections to allow heat to be removed heat from the chip package.

However, as power densities increase, due to increased voltage, decreased chip size, or a combination of both, thermal and electrical management of the chip-substrate configuration shown in FIG. 1 becomes more challenging. One constraint, that of resisting a break down voltage (BDV) becomes increasingly important as power densities increase. In general, for a given dielectric material, larger BDV constraints are accompanied by an increase in the thickness of dielectric material, as is known in the art.

Reference is now made to FIG. 2, which is a schematic diagram of the chip package and substrate of FIG. 1. Apart from differences described below, chip package 10 and substrate 12 are substantially the same as shown in FIG. 1.

The following equation is useful in discussing thermal management issues for chip package 10 and substrate 12, in light of more stringent constraints:

k=Kt*S/h

Wherein:

k=overall thermal conductivity coefficient, nominally expressed as: W/deg C.;

Kₜ=material coefficient of thermal conductivity, nominally expressed as: W/(m*deg C.);

S=thermal path cross sectional area, nominally expressed as: m²

h=thermal path equivalent, nominally expressed as: m

In the ALOX™ process described hereinabove, as well as other processes known in the art, there is a conflict in considerations between the material thermal conductivity versus the material BDV (as described hereinabove), as device voltage requirements increase, thereby inferring concomitant stringent thermal requirements. In general, it may be understood that as “h” is decreased, meaning employing a thinner substrate, there is an increase in Kt; however a thinner substrate is more susceptible to BDV.

There is, therefore, a need for methods and/or systems to more effectively manage higher thermal loads in device/substrate configurations in light of increased BDV requirements, while minimizing costs of device design.

### SUMMARY

According to some embodiments, the present invention relates to methods and systems of thermal-electrical path splitting in high power electronic packages, and in particular, it concerns methods and system of effectively removing heat from high power ALOX™ packages.

According to some embodiments, there is provided an interconnect substrate comprising a valve metal bulk region and a first oxide layer, wherein the first oxide layer comprises at least a first portion having a first thickness and a second portion having a second thickness, wherein the first thickness is smaller than the second thickness, and wherein the first portion is adapted to transfer heat from an electronic device to the bulk region, and wherein the second portion is adapted to electrically isolate a metallic layer from the valve metal bulk region (and also to thermally isolate the metallic layer from the bulk region). The first oxide layer is located on a first surface of the bulk region.

The substrate may further include a second oxide layer located on a second surface of the bulk region, wherein said second surface is on the opposite side of the first surface. The second oxide layer may be adapted to form, together with the first oxide layer, an electrically isolating structure.

According to some embodiments, there is provided a method of producing an interconnect substrate, the method comprising anodizing a valve metal bulk region to form a first oxide layer, wherein the first oxide layer comprises at least a first portion having a first thickness, and a second portion having a second thickness, wherein the first thickness is smaller than the second thickness and wherein the first portion is adapted to transfer heat from an electronic device to the bulk region, and wherein the second portion is adapted to electrically isolate. The method may include anodizing a first surface of the valve metal bulk region to form the first oxide layer. The method may further include anodizing a valve metal bulk region to form a second oxide layer on a second surface of the bulk region, wherein the second surface is on the opposite side of the first surface.

The second oxide layer may be adapted to form, together with the first oxide layer, an electrically isolating structure. The method may further include anodizing the valve metal bulk region to form a multiplicity of oxide layers.

The first thickness may be in the range of 0-100 microns. The second thickness may be in the range of 50-200 microns.

The substrate may further include a multiplicity of oxide layers.

The first oxide layer may be formed by anodization. The second oxide layer may be formed by anodization. The first oxide layer may include ALOX. The second oxide layer may include ALOX.

According to some embodiments, there is provided a method of enhancing thermal management of an electronic device comprising the steps of forming an ALOX™ interconnect substrate, and interconnecting the electronic device to the interconnect substrate to yield a substantial split of thermal and electrical paths in the interconnect substrate. Forming the interconnect substrate may include providing a valve metal substrate, selectively anodizing the substrate to form at least one isolation structure and forming an electrically conductive trace on the at least one isolation structure, the conductive trace electrically isolated from the bulk region.

The method may further include forming an electrically conductive trace on the at least one isolation structure, the conductive trace electrically isolated from the bulk region.

The split of thermal and electrical paths is effected by selectively electrically interconnecting the electronic device to the metal trace, and intimately configuring the electronic device to the substrate to enhance thermal conductance of the thermal path between the device and the bulk region.

Forming the interconnect substrate may include the steps of providing a valve metal substrate, selectively anodizing the substrate to form at least one isolation structure and forming a first electrically conductive trace on the at least one isolation structure, the conductive trace electrically isolated from the bulk region, and forming a second electrically conductive trace in direct contact with the bulk region.

The split between the thermal and conductive paths may be effected by selectively electrically interconnecting the electronic device to the first metal trace and intimately configuring the electronic device to the substrate, to enhance thermal conductance of the thermal path.

The split between the thermal and conductive paths may be effected selectively electrically interconnecting the electronic device to the second metal trace, and intimately configuring the electronic device to the substrate to enhance thermal conductance of the thermal path between the device and the bulk region.

According to some embodiments, there is provided an enhanced thermally managed electronic device comprising an ALOX™ interconnect substrate, and an electronic device, interconnectable to the interconnect substrate, the interconnect substrate having a substantial split of thermal from electrical paths.

The interconnect substrate may further include a valve metal substrate anodizable to form at least one isolation structure therein; and an electrically conductive trace formable on the at least one isolation structure, the conductive trace electrically isolatable from the bulk region.

The split of thermal from conductive paths may include an electrical interconnection of the electronic device to the conductive trace, and a configuration of the electronic device to the substrate, thereby allowing enhancement of thermal conductance of the thermal path between the device and the bulk region.

The at least one isolation structure may serve as a break down voltage isolation between the electronic device and the interconnect substrate. The thickness of the at least one isolation structure may be selectively chosen to enhance thermal conductivity.

According to some embodiments, the valve metal bulk region may include aluminum or any other appropriate metal.

### BRIEF DESCRIPTION OF THE DRAWINGS

The invention is herein described, by way of example only, with reference to the accompanying drawings, wherein:

FIG. 1 is a schematic cross sectional view of a typical high power chip package mounted on a substrate;

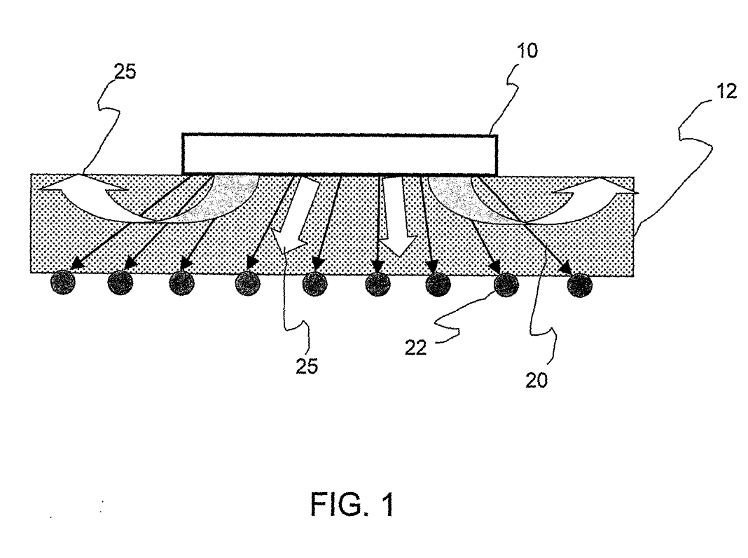

FIG. 2 is a schematic diagram of the chip package and substrate of FIG. 1;

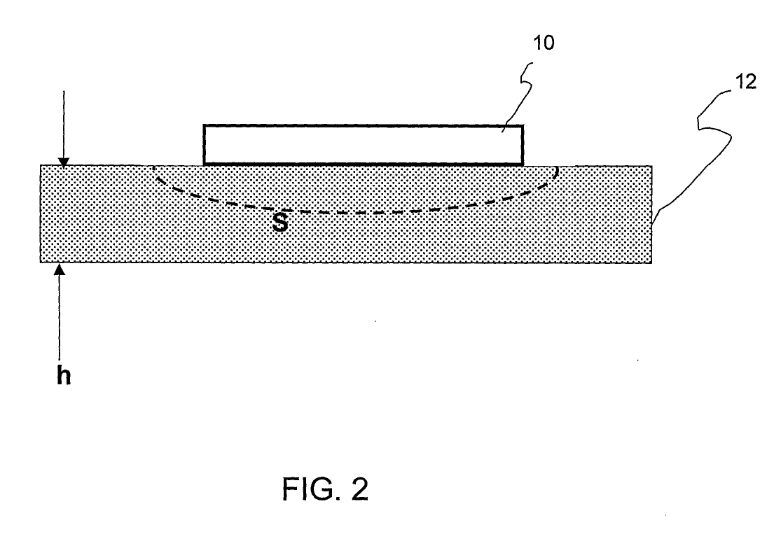

FIG. 3 is a schematic cross sectional diagram of a configuration of a high power chip package mounted on a substrate;

FIG. 4 is a schematic cross sectional diagram of a thermal/electrical path split configuration of a high power chip package mounted on a substrate, in accordance with an embodiment of the current invention;

FIG. 5 is a schematic representation of an improved thermal/electrical path split configuration, in accordance with an embodiment of the current invention;

FIG. 6 is a schematic representation of an improved thermal/electrical path split two-sided configuration, in accordance with an embodiment of the current invention; and

FIGS. 7A and 7B are schematic representations of two fabrication stages of the substrate shown in FIG. 6, in accordance with an embodiment of the current invention.

### DESCRIPTION OF THE PREFERRED EMBODIMENTS

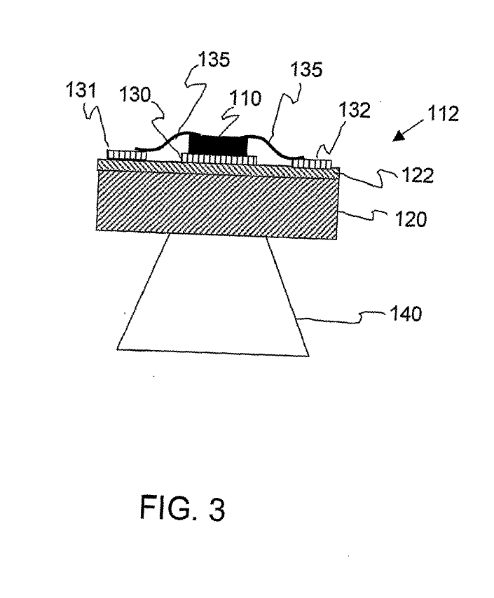

Reference is now made to FIG. 3, which is a schematic cross sectional diagram of a configuration 100 of a high power chip package 110 mounted on a substrate 112. In configuration 100, substrate 112 comprises a bulk region 120, upon which is formed an oxide layer 122, upon which are formed patterned metallic layers 130 and 132. Bulk region 120 is in close contact with heat sink 140, which serves to conduct heat from the substrate to the outside world (not shown in the figure). Chip package 110 is mounted on metallic layer 130, which has been patterned to support and electrically contact the chip package. Metallic layers 131 and 132 have been patterned to provide electrically conductive paths for leads 135. Whereas metallic layers 130 and 132 are typically (although not mandatorily) formed concurrently, and they are typically substantially identical in terms of thickness and material, their respective patterns differ and serve to separately conduct electricity to the leads and to the base of chip package 110 from separate electrical paths. One candidate material for metallic layers is copper. Patterning of the layers, as described hereinabove, is typically performed using resist, as know in the art. The resultant patterned metal layer is also referred to, in the specification and in the claims which follow, as an “electrically conductive trace”.

Whereas leads 135 are indicated in the current figures as stretching to the left and to the right to metallic layers 130, additional leads (not shown in the figures) may also be present, and they may extend substantially perpendicular into and out of the plane of the figures, contacting metal layers (not shown) configured not in the plane of the figures. Similarly, patterned metallic layers 131 and 132 may extend into and out of the plane of the figure. An electrical path (for example chip package 110 via leads 135 to metal layers 131 and 132) is formed. Oxide layer 122 serves to electrically isolate the metallic layers from the bulk region. As such, whereas oxide layer 122 offers some resistance to heat transfer from chip package 110 to the bulk region 120 and to the heat sink 140, the effect of thermal resistance may be offset by decreasing the thickness of oxide layer 122 and by its intrinsically large area, all according to the equation noted hereinabove.

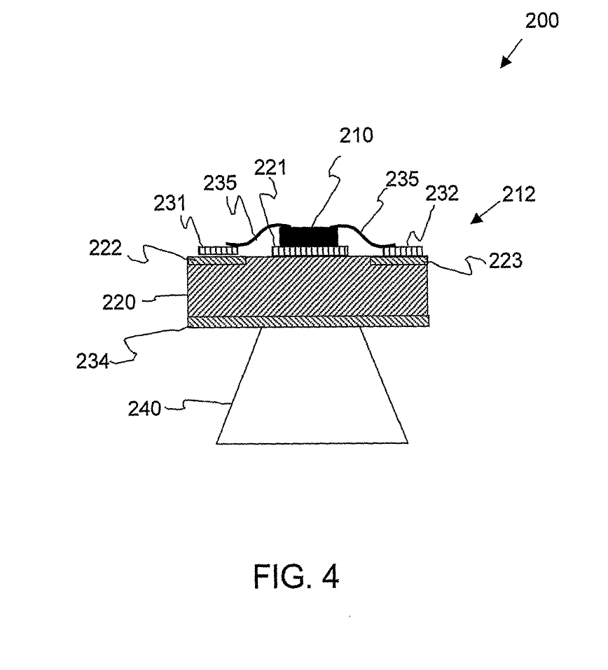

Reference is now made to FIG. 4, which is a schematic cross sectional diagram of a thermal/electrical path split configuration 200 of a high power chip package 210 mounted on a substrate 212, in accordance with an embodiment of the current invention. In configuration 200, chip package 210 is electrically and thermally connected to bulk region 220 by way of metallic layer 221. This configuration, yielding a thermal path of chip package 210 to metallic layer 221 to bulk region 220, is typical of a connection where the bulk region also serves as a ground or as a common bias voltage, for example. This configuration is highly advantageous to removing heat directly from chip package 210—especially for a chip package having high power density—while serving to split an electrical path (for example, chip package 210 to leads 235 to metallic layers 231) from the thermal path. Oxide layers 222 and 223 are selectively formed under metal layers 231 and 232 (as described for substrate 112 hereinabove), but the oxide layers are formed only substantially under the metallic layers, thereby affording electrical resistance between the metallic layers and bulk region 220. (Note that there is no oxide layer under metallic layer 221.) The electrical path of chip package 210 to metallic layer 221 to bulk region 220 is isolated from heat sink 240 by way of oxide layer 234 formed on the surface of the bulk region where it contacts the heat sink, as shown in the figure. Oxide layers 222, 223, and 234 effectively serve as electrical isolation structures. Examples of bulk region 220 material are valve materials, as noted hereinabove. One example of the material of the metallic layers is copper.

In FIG. 4, the range of power values of chip package 210 may vary from approximately 10 to 1000 W, and preferably from 30 to 500 W. The thickness of substrate 212 may range from approximately 0.010 to 5 mm and preferably from 0.030 to 3 mm. Other typical, approximate ranges of material/layer thicknesses are: oxide layers 222, 223, and 234, ranging from 10 to 300 um; metal layers 221, 222, and 232 ranging from 1-100 um; and metallic layer 132, ranging from 10-100 um.

Representative BDV value ranges of the chip package and substrate are from 100 to 6000V. Power values, thickness values, and BDV values noted hereinabove are likewise appropriate to chip packages and substrates described hereinbelow.

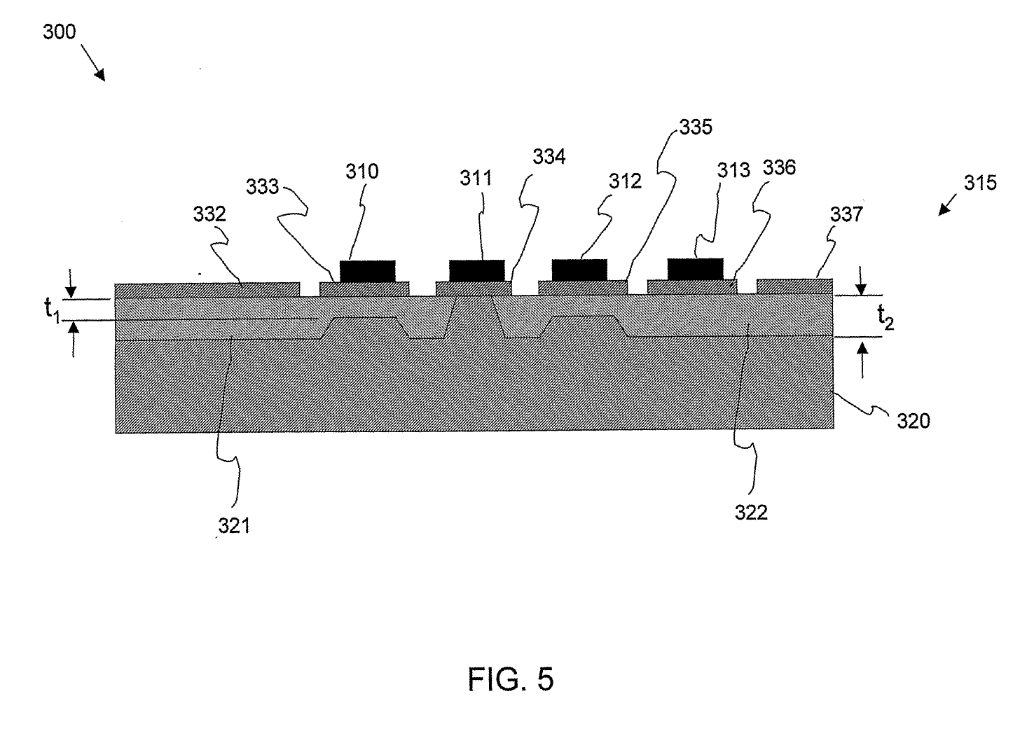

Reference is now made to FIG. 5, which is a schematic representation of an improved thermal/electrical path split configuration 300, in accordance with an embodiment of the current invention. Apart from differences described below, chip packages 310, 311, 312, and 313 and substrate 315 are generally similar in configuration, operation, and functionality as described hereinabove to the chip package and the substrate shown in FIG. 4. Metallic layers 332, 333, 334, 335, 336, and 337 are selectively formed, as shown, to provide contact under chip packages 310, 311, 312, and 313, respectively. The metallic layers comprise electrically conductive traces which typically have paths perpendicular to the plane of the figure. Oxide layers 321 and 322 are selectively formed, having varying thicknesses, as schematically shown in the figure, to provide varying levels of electrical isolation between the metallic layers and bulk region 320. Specifically, but not limited to this example, chip packages 310 and 312 are located above the oxide layers having thicknesses indicated as t₁, whereas chip package 313 is located above the oxide layer having a thickness indicated as t₂. Furthermore, oxide layers 321 and 322 are selectively formed under chip packages 311 to have substantially no thickness, thereby yielding a maximal thermal path (and in this case, an electrical path similar to that noted in FIG. 4) between chip package 311 to the bulk region, as described hereinabove in FIG. 4. Thermal/electrical path split configuration 300 schematically shows how selectively controlling the thicknesses of the oxide is employed to thermally manage a number of chip packages, according to the relative configuration and power densities of the specific chip packages.

The oxide layer is made thicker (for example, t₂), usually on the order of 50 to 200 microns, for example, where the chip packages have lower power densities, typically on the order of 1-10 W/cm². The oxide layer is formed with a smaller thickness (for example, t₁), typically on the order of 10 to 100 microns, where chip packages 110 have higher power densities, typically on the order of tens and hundreds of W/cm², for example the range of 10-300 W/cm². Alternatively or optionally, in the example shown in the current figure, where a plurality of chip packages are configured relatively close to one another, yielding a higher overall power density for the overall configuration of chip packages, it is advantageous to selectively enhance the thermal paths for one or more chip packages having other chips nearby (for example, enhancing the thermal paths of chip packages 311 and 312). In this case, enhancement of thermal paths is typically accomplished by reducing the oxide thickness, for example, t₁. In regions where the enhancement of the thermal path is not required, such as under chip package 313, a thicker oxide, for example, t₂ is employed.

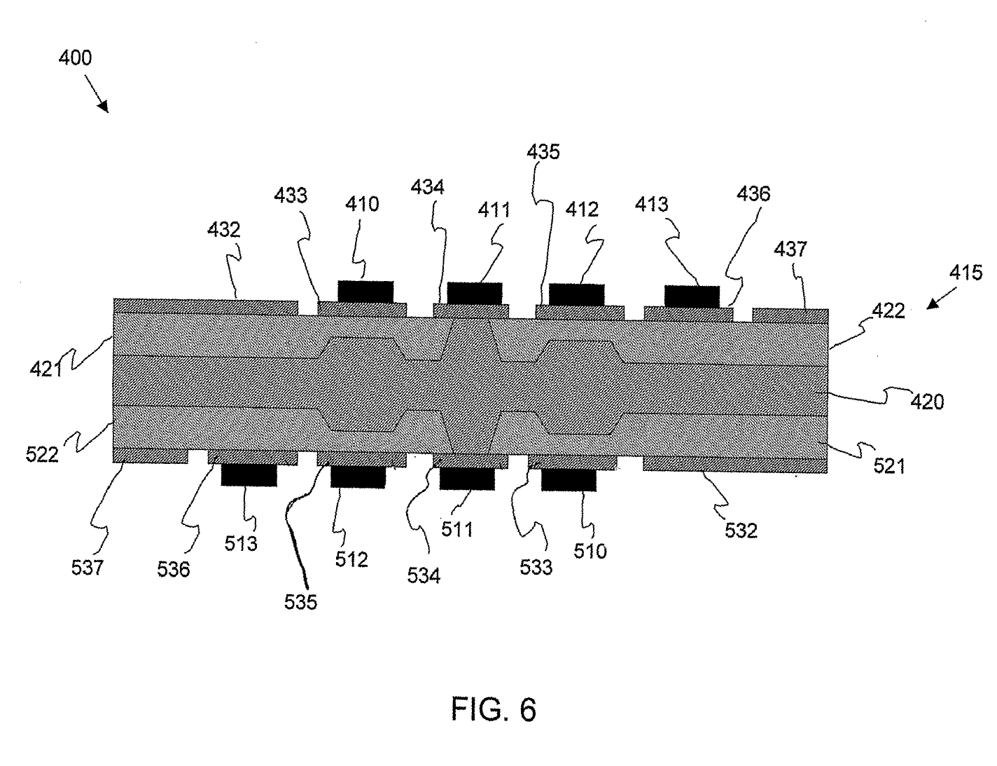

Reference is now made to FIG. 6, which is a schematic representation of an improved thermal/electrical path split two-sided configuration 400, in accordance with an embodiment of the current invention. Apart from differences described below, chip packages 410, 411, 412, 413, 510, 511, 512 and 513 of substrate 415 are generally similar in configuration, operation, and functionality as described for the chip packages and the substrate shown in FIG. 5. In configuration 400, it can be seen that the chip packages are mounted on two surfaces of substrate 415 and that metallic layers 432, 433, 434, 435, 436, 437, 532, 533, 534, 535, 536, and 537 are selectively formed, as shown, to provide contact between the chip packages and the substrate. The metallic layers comprise electrically conductive traces, which typically have paths perpendicular to the plane of the figure. Oxide layers 421, 422, 521 and 522 are selectively formed, having varying thicknesses, as schematically shown in the figure, to provide varying levels of electrical isolation between the metallic layers and bulk region 420.

Chip packages 411 and 511 are configured with combined electrical and thermal paths to the bulk region, analogously to that shown for chip package 311 in FIG. 5. In the current figure, utilization of two surfaces of the substrate can be advantageous to increase the number of chips in a given space (for example, increased chip density) and to effectively manage thermal and electrical paths of the chips. Typical oxide layer thicknesses, metallic layer thicknesses, and power densities of the chip packages are as noted hereinabove.

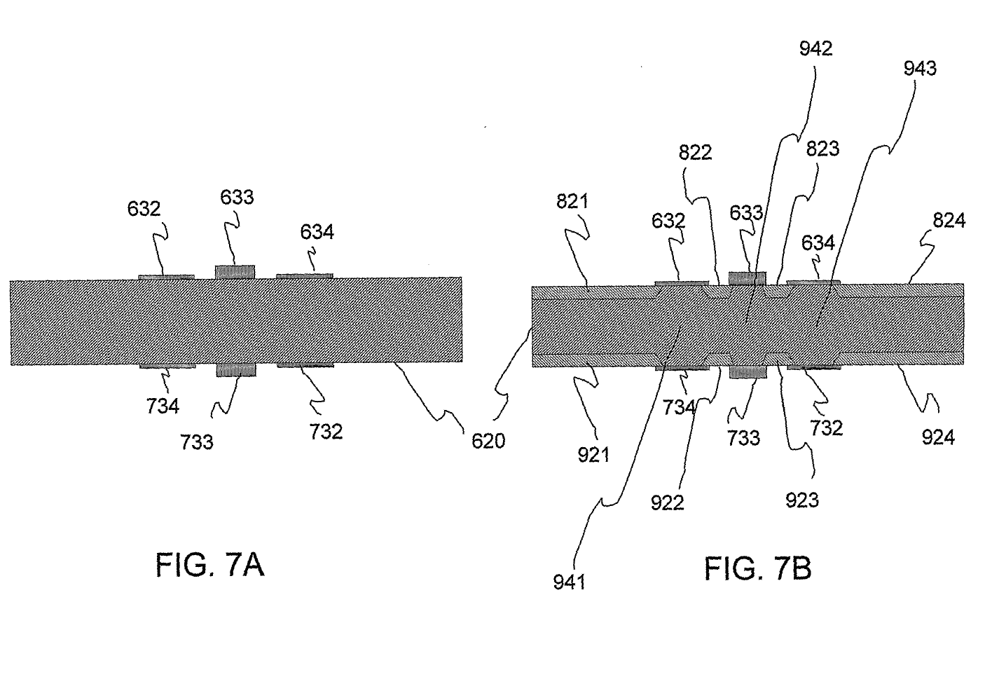

Reference is now made to FIGS. 7A and 7B, which are schematic representations of two fabrication stages of the substrate shown in FIG. 6. Apart from differences described below, bulk region 620 is generally similar to the bulk region configuration, operation, and functionality as described previously shown in FIG. 6.

Referring to FIG. 7A, fabrication steps to selectively form metallic layers 632, 633, 634, 732, 733, and 734 include: metal deposition (such as, but not limited to sputtering); masking (for example, application of photo resist); metal etching (typically including metallization removal and selective anodization of the bulk region); and resist removal—as known in the art.

Referring to FIG. 7B, oxide layers 821, 822, 823, 824, 921, 922, 923, and 924 are typically formed by masking (for example, application of photo resist); anodization of the bulk region, and photo resist removal, as known in the art. These steps may be repeated to provide selectively deeper anodization regions, thereby yielding oxide layers with thinner and thicker regions as necessary.

Resultant oxide layers allow the substrate to be processed, forming one or more cavities 941, 942 and 943 (for example, regions of conductive aluminum in the bulk region contacting the metallic layers with insulating oxide layers on the surfaces of the substrate) for electrical conduction from one side to the other of the substrate—refer to U.S. Patent Application Publication No. 2007/0080360 noted hereinabove. Alternatively or additionally, the substrate may be formed with deep anodization (for example, thicker oxide layers, not shown in the figure) to yield formation of electrical vias, as know in the art. Whereas FIGS. 7A and 7B show fabrication steps for a two-sided substrate configuration, a one-sided configuration (for example, as show in FIG. 5) may also be fabricated mutatis mutandis.

Additionally, although exemplary configurations in FIGS. 4, 5, and 6 show one or more chip packages mounted directly on the metallic layer with no oxide layer separating the metallic layer from the bulk region, embodiments of the current invention may include additional chip packages likewise mounted or, alternatively, no chip packages mounted directly on the metallic layer with no oxide layer separating the metallic layer from the bulk region.

It will be appreciated that the above descriptions are intended only to serve as examples, and that many other embodiments are possible within the scope of the present invention as defined in the appended claims.

1.-42. (canceled)

43. An interconnect substrate comprising:
a valve metal bulk region; and
a first oxide layer,
wherein the first oxide layer comprises at least a first portion having a first thickness and a second portion having a second thickness, wherein the first thickness is smaller than the second thickness and wherein the first portion is adapted to transfer heat from an electronic device to the bulk region and wherein the second portion is adapted to electrically isolate.

44. The substrate according to claim 43, wherein the first oxide layer is located on a first surface of the bulk region.

45. The substrate according to claim 44, further comprising second oxide layer located on a second surface of the bulk region, wherein said second surface is opposing to the first surface.

46. The substrate according to claim 44, wherein the second oxide layer is adapted to form, together with the first oxide layer, an electrically isolating structure.

47. The substrate according to claim 43, wherein the first thickness is in the range of 0-100 microns.

48. The substrate according to claim 43, wherein the second thickness is in the range of 50-200 microns.

49. The substrate according to claim 43, further comprising a multiplicity of oxide layers.

50. The substrate according to claim 43, wherein the valve metal bulk comprises aluminum.

51. The substrate according to claim 43, wherein the first oxide layer, the second oxide layer or both were formed by anodization.

52. The substrate according to claim 43, wherein the first oxide layer, the second oxide layer or both comprise aluminum oxide (ALOX).

53. A method of producing an interconnect substrate, the method comprising:
anodizing a valve metal bulk region to form a first oxide layer, wherein the first oxide layer comprises at least a first portion having a first thickness and a second portion having a second thickness, wherein the first thickness is smaller than the second thickness and wherein the first portion is adapted to transfer heat from an electronic device to the bulk region and wherein the second portion is adapted to electrically isolate.

54. The method according to claim 53, comprising anodizing a first surface of the valve metal bulk region to form the first oxide layer.

55. The method according to claim 53, further comprising anodizing a valve metal bulk region to form a second oxide layer on a second surface of the bulk region, wherein the second surface is opposing to the first surface.

56. The method according to claim 55, wherein the second oxide layer is adapted to form, together with the first oxide layer, an electrically isolating structure.

57. The method according to claim 55, wherein the first thickness is in the range of 0-100 microns.

58. The method according to claim 53, further comprising anodizing the valve metal bulk region to form multiplicity of oxide layers.

59. The method according to claim 53, wherein the valve metal bulk comprises aluminum.

60. The method according to claim 55, wherein the first oxide layer, the second oxide layer or both were formed by anodization.

61. The method according to claim 55, wherein the first oxide layer, the second oxide layer or both comprises ALOX.

62. A method of enhancing thermal management of an electronic device comprising the steps of:
forming an ALOX interconnect substrate;
interconnecting the electronic device to the interconnect substrate to yield a substantial split of thermal and electrical paths between the substrate and the electronic device.

63. A method according to claim 62, wherein forming an interconnect substrate comprises the steps of:
providing a valve metal substrate;
selectively anodizing the substrate to form at least one isolation structure; and
forming an electrically conductive trace on the at least one isolation structure, the conductive trace electrically isolated from the bulk region.

64. A method according to claim 63, further comprising forming an electrically conductive trace on the at least one isolation structure, the conductive trace electrically isolated from the bulk region.

65. The method of claim 63, wherein the valve metal is aluminum.

66. The method of claim 63, wherein the split of thermal and electrical paths is effected by: selectively electrically interconnecting the electronic device to the metal trace; intimately configuring the electronic device to the substrate to enhance thermal conductance of the thermal path between the device and the bulk region.

67. A method according to claim 66, wherein the at least one isolation structure serves as a break down voltage isolation between the electronic device and the interconnect substrate.
